(19) United States
(12) Patent Application Publication
(10) Pub. No.: US 2012/0162883 A1
(43) Pub. Date: Jun. 28, 2012

(54) DATA PROCESSING APPARATUS AND POWER CONNECTION MECHANISM AND METHOD THEREOF

(75) Inventor: Ben-Chiao Jai, Taoyuan Hsien (TW)

(73) Assignee: DELTA ELECTRONICS, INC., Taoyuan Hsien (TW)

(21) Appl. No.: 13/076,180

(22) Filed: Mar. 30, 2011

(30) Foreign Application Priority Data
Dec. 23, 2010 (TW) 099145647

(51) Int. Cl. G06F 1/16; H05K 13/00; H05K 7/00

(52) U.S. Cl. 361/679.02; 361/679.01; 29/825

(57) ABSTRACT

A data processing apparatus includes a rack cabinet, a power distribution unit and at least one modular electronic device. The rack cabinet includes a frame assembly and a receiving part. The power distribution unit is disposed on the frame assembly, and includes a plurality of first electric connectors. The modular electronic device includes a second electric connector and is swappable to be accommodated within a corresponding compartment of the receiving part. The second electric connector fits a corresponding first electric connector. After the modular electronic device is accommodated within the compartment, the second electric connector is directly connected with the corresponding first electric connector of the power distribution unit in a blind-mating manner.

### FIELD OF THE INVENTION

The present invention relates to a data processing apparatus, and more particularly to a data processing apparatus capable of directly connecting a modular electronic device with a power distribution unit in a blind-mating manner. The present invention relates to a power connection mechanism of the data processing apparatus.

### BACKGROUND OF THE INVENTION

With increasing development of information industries and networks, the services provided through networks are becoming more and more popular in various applications. A data center is a facility used to house computers or servers. For providing intensive network applications, the numbers of computers or servers of the data center need to be increased to transmit, process, access and communicate data at high speed.

Nowadays, the data center comprises a plurality of data processing apparatuses. Each data processing apparatus comprises a rack cabinet and a plurality of modular electronic devices. The rack cabinet has a receiving part for accommodating these modular electronic devices. FIG. 1A schematically illustrates a rack cabinet and a power distribution unit of a data processing apparatus according to the prior art. FIG. 1B schematically illustrates the connection between the modular electronic device and the power distribution unit through a power cord according to the prior art. Generally, at least one power distribution unit (PDU) 11 is installed on an inner surface of the rack cabinet 10 of the data processing apparatus 1. The power distribution unit 11 is configured for distributing external electric power to a plurality of modular electronic devices 12. Generally, the power distribution unit 11 and the modular electronic devices 12 are connected with each other through the same number of power cords 13 as the modular electronic devices 12. In such way, many power cords 13 are exposed after the modular electronic devices 12 are installed within the rack cabinet 10 of the data processing apparatus 1. As known, too many power cords become hindrance from managing the data processing apparatus 1 and increase the fabricating cost of the data processing apparatus 1.

Moreover, for arranging the data processing apparatuses in the data center, many factors such as heat-dissipating efficacy, space utilization, and ease of management and maintenance should be taken into consideration. Generally, after the modular electronic devices 12 are installed within the rack cabinet 10 of the data processing apparatus 1, the modular electronic devices 12 are connected with the power distribution unit 11 through the power cords 13 at the backside of the rack cabinet 10. Then, the whole data processing apparatus 1 is moved to a specified location of the data center to enhance the space utilization and the heat-dissipating efficacy. However, some drawbacks occur during the process of maintaining the data processing apparatus 1. For example, in a case that the regular maintenance of the modular electronic device 12 (e.g. a computer or a server) is made or the modular electronic device 12 needs to be replaced, since the working space in the backside of the rack cabinet 10 is usually very narrow, the rack cabinet 10 should be moved to expand the working space to allow the worker to detach the power cords 13. Until the power cords 13 between the power distribution unit 11 and the modular electronic devices 12 are detached, the worker may withdraw the modular electronic devices 12 to perform the maintenance task or replace the modular electronic devices 12. From the above discussions, it is inconvenient, time-consuming and labor-intensive to perform the maintenance task of the data processing apparatus and replace the modular electronic devices.

### SUMMARY OF THE INVENTION

The present invention provides a data processing apparatus capable of directly connecting a modular electronic device with a power distribution unit in a blind-mating manner without the need of using the power cords. Consequently, it is not necessary to move the rack cabinet to detach the power cords during the process of maintaining or replacing the modular electronic device.

The present invention also provides a data processing apparatus capable of directly connecting a modular electronic device with a power distribution unit in a blind-mating manner, so that it is labor-saving and time-saving to install and maintain the data processing apparatus.

In accordance with an aspect of the present invention, there is provided a data processing apparatus. The data processing apparatus includes a rack cabinet, a power distribution unit and at least one modular electronic device. The rack cabinet includes a frame assembly and a receiving part. The power distribution unit is disposed on the frame assembly, and includes a plurality of first electric connectors. The modular electronic device includes a second electric connector and is swappable to be accommodated within a corresponding compartment of the receiving part. The second electric connector fits a corresponding first electric connector. After the modular electronic device is accommodated within the compartment, the second electric connector is directly connected with the corresponding first electric connector of the power distribution unit.

In accordance with another aspect of the present invention, there is provided a power connection mechanism of a data processing apparatus. The data processing apparatus includes a rack cabinet with a frame assembly and a receiving part. The power connection mechanism includes a power distribution unit and at least one modular electronic device. The power distribution unit is disposed on the frame assembly, and includes a plurality of first electric connectors. The modular electronic device includes a second electric connector and is swappable to be accommodated within a corresponding compartment of the receiving part. The second electric connector fits a corresponding first electric connector. After the modular electronic device is accommodated within the compartment, the second electric connector is directly connected with the corresponding first electric connector of the power distribution unit in a blind-mating manner.

In accordance with another aspect of the present invention, there is provided a power connection method. The power connection method comprises the steps of providing a rack cabinet, a power distribution unit and at least one modular electronic device, wherein the rack cabinet has a frame assembly and a receiving part, the power distribution unit is disposed on the frame assembly and comprises a plurality of first electric connectors, and the modular electronic device comprises a second electric connector that fits a corresponding first electric connector; and accommodating the modular electronic device within the rack cabinet, and allowing the second electric connector of the modular electronic device to be directly connected with the corresponding first electric connector of the power distribution unit.

The above contents of the present invention will become more readily apparent to those ordinarily skilled in the art after reviewing the following detailed description and accompanying drawings, in which:

### BRIEF DESCRIPTION OF THE DRAWINGS

FIG. 1A schematically illustrates a rack cabinet and a power distribution unit of a data processing apparatus according to the prior art;

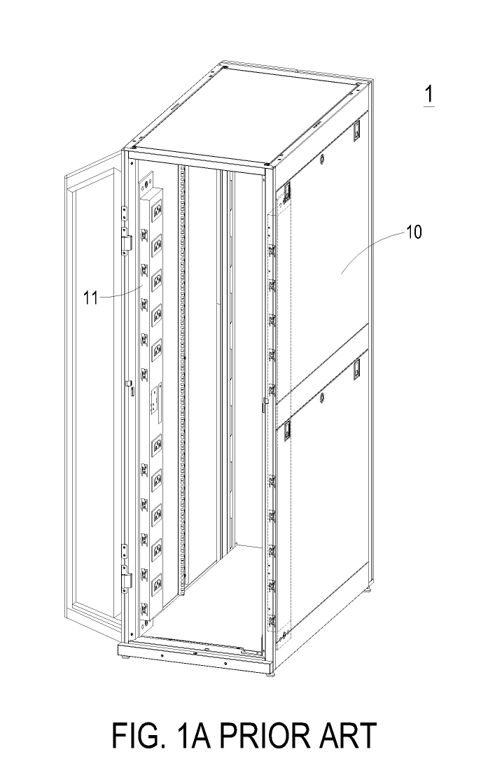

FIG. 1B schematically illustrates the connection between the modular electronic device and the power distribution unit through a power cord according to the prior art;

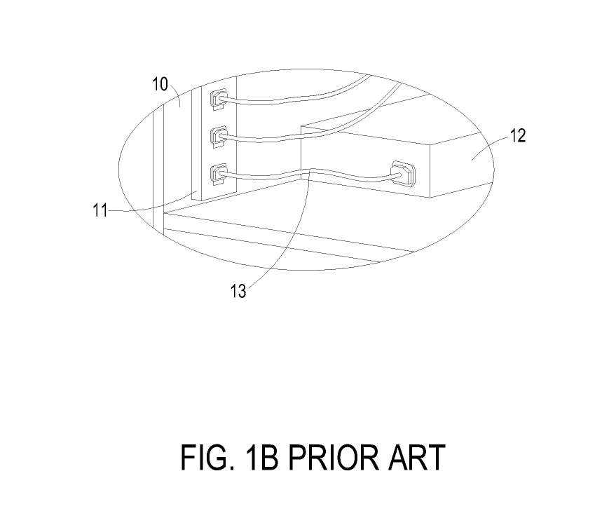

FIG. 2 is a schematic perspective view illustrating a data processing apparatus according to an embodiment of the present invention;

FIG. 3A schematically illustrates a power connection mechanism of the data processing apparatus of FIG. 2;

FIG. 3B schematically illustrates the connection between the modular electronic device and the power distribution unit through the power connection mechanism of FIG. 2; and

FIG. 4 is a flowchart illustrating a power connection method of the data processing apparatus according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

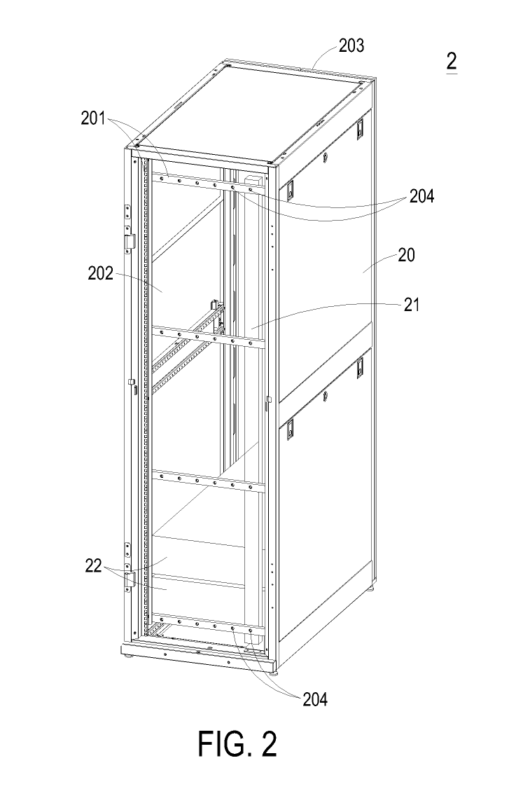

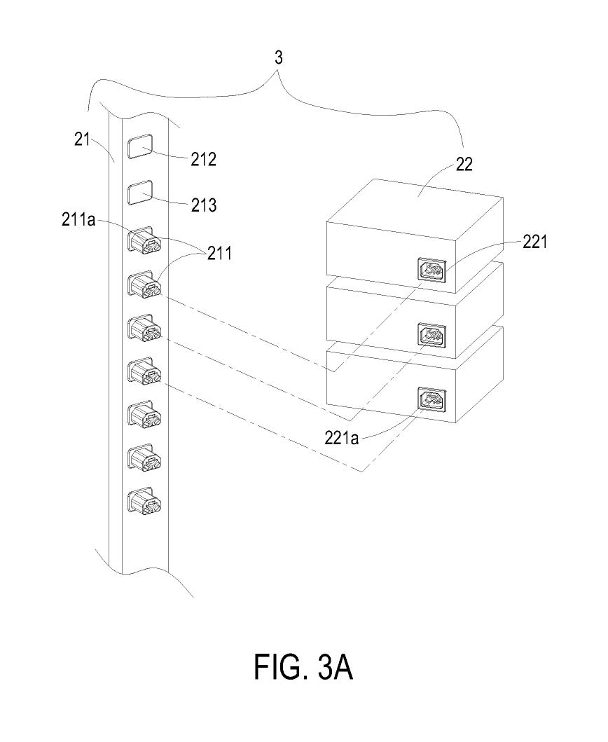

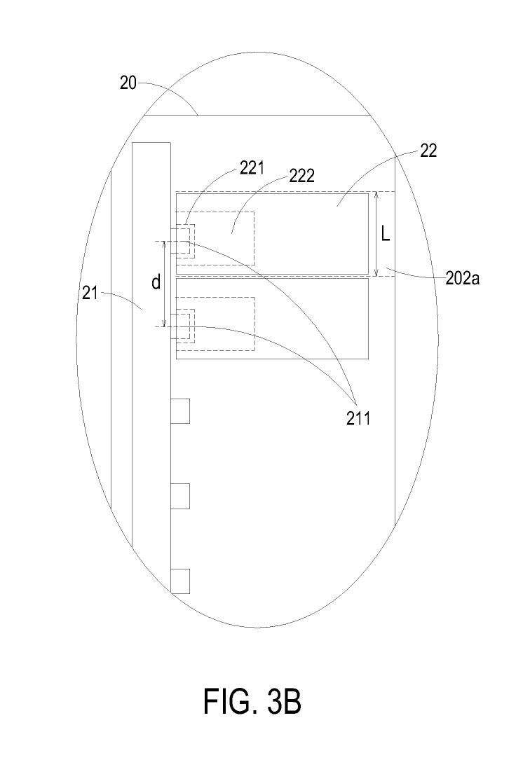

FIG. 2 is a schematic perspective view illustrating a data processing apparatus according to an embodiment of the present invention. FIG. 3A schematically illustrates a power connection mechanism of the data processing apparatus of FIG. 2. FIG. 3B schematically illustrates the connection between the modular electronic device and the power distribution unit through the power connection mechanism of FIG. 2. Please refer to FIGS. 2, 3A and 3B. The data processing apparatus 2 comprises a rack cabinet 20, a power distribution unit 21 and one or more modular electronic devices 22. Examples of the modular electronic devices 22 include but are not limited to computers or servers. The rack cabinet 20 comprises a frame assembly 201 and a receiving part 202. The receiving part 202 comprises a plurality of compartments 202a for accommodating corresponding modular electronic devices 22. The power distribution unit 21 is disposed on the frame assembly 201 of the rack cabinet 20. It is preferred that the power distribution unit 21 is fixed on a backside of the frame assembly 201 of the rack cabinet 20. The power distribution unit 21 comprises a plurality of first electric connectors 211 corresponding to respective compartments 202a of the rack cabinet 20. Each of the modular electronic devices 22 comprises a second electric connector 221 and a power supply unit 222. In addition, the modular electronic device 22 is swappable to be accommodated within a corresponding compartment 202a. The second electric connector 221 fits a corresponding first electric connector 211. After a modular electronic device 22 is accommodated within a corresponding compartment 202a of the rack cabinet 20, the second electric connector 221 of the modular electronic device 22 is swappable to be plugged in a corresponding first electric connector 211 of the power distribution unit 21. The power distribution unit 21 and the modular electronic devices 22 of the data processing apparatus 2 are defined as a power connection mechanism 3. Through the power connection mechanism 3, the modular electronic devices 22 can be plugged into the power distribution unit 21 within the rack cabinet 20 in a blind-mating manner without the need of using the power cords.

Please refer to FIGS. 3A and 3B again. In this embodiment, the first electric connectors 211 and the second electric connectors 221 comply with the IEC (International Electrotechnical Commission) specifications. For example, the first electric connector 211 is an IEC C13 connector, and the second electric connector 221 is an IEC C14 connector. Alternatively, the first electric connector 211 is an IEC C13 connector with a pin insulation structure and/or a detecting pin, and the second electric connector 221 is an IEC C14 connector with another pin insulation structure and/or another detecting pin. It is noted that the first electric connector 211 and the second electric connector 221 may be any two kinds of connectors that fit each other. For example, the first electric connector 211 and the second electric connector 221 are the IEC C15 connector and the IEC C16 connector, respectively. Moreover, one or both of the first electric connector 211 and the second electric connector 221 have guiding parts 211a and 221a such as bevel profiles. The guiding parts 211a and 221a can facilitate easy connection between the first electric connector 211 and the second electric connector 221 in a blind-mating manner.

Please refer to FIGS. 3A and 3B again. The first electric connectors 211 of the power distribution unit 21 are discretely arranged at regular intervals d. The regular interval d is substantially equal to the height L of a corresponding compartment 202a. In some embodiments, the power distribution unit 21 further comprises a communication module 212 and a controlling module 213. Through the communication module 212, the data processing apparatus 2 can be in communication with a remote controlling device through the internet. The controlling module 213 is configured to control and manage the power distribution status and the power supply status of the power distribution unit 21. In other words, the functions of remotely controlling and managing power can be implemented by means of the communication module 212 and the controlling module 213.

The power distribution unit 21 is disposed on the frame assembly 201 of the rack cabinet 20. It is preferred that the power distribution unit 21 is fixed on a backside of the frame assembly 201 of the rack cabinet 20. Moreover, the first electric connectors 211 of the power distribution unit 21 face the front surface 203 of the rack cabinet 20. In some embodiments, the rack cabinet 20 or the power distribution unit 21 further comprises a plurality of positioning structures 204. Through the positioning structures 204, the location of the power distribution unit 21 relative to the frame assembly 201 in the horizontal direction is adjustable.

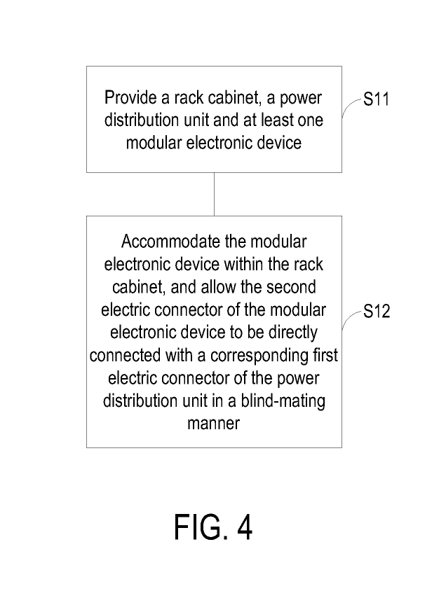

FIG. 4 is a flowchart illustrating a power connection method of the data processing apparatus according to an embodiment of the present invention. Please refer to FIGS. 2, 3A, 3B and 4. Firstly, in the step S11, a rack cabinet 20, a power distribution unit 21 and at least one modular electronic device 22 are provided. The power distribution unit 21 is disposed on a frame assembly 201, and comprises a plurality of first electric connectors 211. The modular electronic device 22 comprises a second electric connector 221 that fits a corresponding first electric connector 211. Then, in the step S12, the modular electronic device 22 is swappable to be accommodated within the rack cabinet 20, wherein the second electric connector 221 of the modular electronic device 22 is directly connected with the corresponding first electric connector 221 of the power distribution unit 21 in a blind-mating manner.

From the above description, the present invention provides a data processing apparatus and a power connection mechanism thereof. Through the connector of the power distribution unit and the connector of the modular electronic device, the modular electronic devices can be plugged into the power distribution unit within the rack cabinet in a blind-mating manner without the need of using the power cords. For maintaining or replacing the modular electronic device, it is not necessary to move the rack cabinet to detach the power cords. After the modular electronic device is accommodated within the rack cabinet, the electric connector of the modular electronic device is directly connected with a corresponding electric connector of the power distribution unit in a blind-mating manner. Consequently, it is labor-saving and time-saving to install and maintain the data processing apparatus.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A data processing apparatus, comprising:
a rack cabinet comprising a frame assembly and a receiving part;
a power distribution unit disposed on said frame assembly, and comprising a plurality of first electric connectors; and
at least one modular electronic device comprising a second electric connector and swappable to be accommodated within a corresponding compartment of said receiving part, wherein said second electric connector fits a corresponding first electric connector, wherein after said modular electronic device is accommodated within said compartment, said second electric connector is directly connected with said corresponding first electric connector of said power distribution unit.

2. The data processing apparatus according to claim 1, wherein said modular electronic device is a computer or a server.

3. The data processing apparatus according to claim 1, wherein said first electric connectors of said power distribution unit and said second electric connector of said modular electronic device are IEC connectors.

4. The data processing apparatus according to claim 3, wherein said first electric connector and said second electric connector are respectively an IEC C13 connector and an IEC C14 connector, or said first electric connector and said second electric connector are respectively an IEC C15 connector and an IEC C16 connector.

5. The data processing apparatus according to claim 1, wherein at least one of said first electric connectors of said power distribution unit and said second electric connector of said modular electronic device has a guiding part.

6. The data processing apparatus according to claim 1, wherein said first electric connectors of said power distribution unit are discretely arranged at regular intervals.

7. The data processing apparatus according to claim 1, wherein an interval between any two adjacent first electric connectors of said power distribution unit is equal to a height of said compartment.

8. The data processing apparatus according to claim 1, wherein said power distribution unit or said rack cabinet further comprises a plurality of positioning structures, wherein through said positioning structures, a location of said power distribution unit relative to said rack cabinet is adjustable.

9. The data processing apparatus according to claim 1, wherein said modular electronic device further comprises a power supply unit.

10. The data processing apparatus according to claim 1, wherein said modular electronic device further comprises a communication module and a controlling module.

11. A power connection mechanism of a data processing apparatus, said data processing apparatus comprising a rack cabinet with a frame assembly and a receiving part, said power connection mechanism comprising:
a power distribution unit disposed on said frame assembly, and comprising a plurality of first electric connectors; and
at least one modular electronic device comprising a second electric connector and swappable to be accommodated within a corresponding compartment of said receiving part, wherein said second electric connector fits a corresponding first electric connector, wherein after said modular electronic device is accommodated within said compartment, said second electric connector is directly connected with said corresponding first electric connector of said power distribution unit in a blind-mating manner.

12. A power connection method, comprising:
providing a rack cabinet, a power distribution unit and at least one modular electronic device, wherein said rack cabinet has a frame assembly and a receiving part, said power distribution unit is disposed on said frame assembly and comprises a plurality of first electric connectors, and said modular electronic device comprises a second electric connector that fits a corresponding first electric connector; and
accommodating said modular electronic device within said rack cabinet, and allowing said second electric connector of said modular electronic device to be directly connected with said corresponding first electric connector of said power distribution unit.
